(19) United States
(12) Patent Application Publication
(10) Pub. No.: US 2006/0061493 A1
(43) Pub. Date: Mar. 23, 2006

(54) Apparatus and method for assigning circuit card base addresses using thermometer codes

(76) Inventors: Lee A. Larson, Katy, TX (US); Ronald L. Lerner, Houston, TX (US)

Correspondence Address: TEXAS INSTRUMENTS INCORPORATED, P O BOX 655474, M/S 3999, DALLAS, TX, 75265, US

(21) Appl. No.: 10/946,788

(22) Filed: Sep. 22, 2004

(51) Int. Cl. H03M 7/00

(52) U.S. Cl. 341/50

(57) ABSTRACT

In plurality of series-coupled circuit boards, a thermometer code is used to provide the address signals for the circuit board. Each terminal of the circuit board input connector is coupled next successive terminal of the circuit board output connector. The terminals of the circuit board input connectors are coupled, through a pull-up resistor, to a voltage source. The least significant terminal of the output terminal can provide a logic signal opposite to the logic signal provided by the voltage source. The address lines for the circuit board are coupled to the terminals of the input connector. In this manner a thermometer address code can be provided for the sequence of series-coupled circuit boards. According to the present invention, the thermometer codes can be expanded with selected additional apparatus.

### 1. FIELD OF THE INVENTION

This invention relates to the assignment of a base address for circuit cards coupled to a bus and, more particularly, to the use of thermometer codes that assign addresses based on the physical location of the circuit board. The invention finds particular application to the assignment of addresses for stackable circuit boards.

### 2. BACKGROUND OF THE INVENTION

In the past, systems employing a bus such as PCI, ISA, or VME have used various techniques to assign unique addresses for the coupled circuit cards. The techniques include jumper conductors, address switches, fixed IDs based on codes wired to the bus connectors and auto configuration capability.

One address coding technique is the thermometer address code. In this code, all the bits to the left of the code value are either 1s or 0s, while all bits to the right of the code value are the same, but have an opposite state from the bits on the left side of the code value. This coding technique provides N+1 unique values for N bits of coding. An example of a 5-bit thermometer code is shown in FIG. 1.

A need has been felt for apparatus and an associated method having the feature of generating thermometer address codes in a group of series-coupled circuit boards. It would be a further feature of the apparatus and associated method that the thermometer code would be generated automatically upon the coupling of the circuit boards. It would be yet a further feature of the apparatus and associated method to provide for an expanded thermometer address code. It would be still further feature of the apparatus and associated method to designate automatically a master circuit board for the group of circuit boards. It would be yet another feature of the apparatus and associated method to compare the thermometer address code with an input address to provide a board select signal when the two addresses are equivalent.

### SUMMARY OF THE INVENTION

The aforementioned and other features are accomplished, according to the present invention, by providing each circuit board with an input and output connector that are coupled by having each input terminal of the input connector coupled to the next sequential terminal of the output connector. In addition, each terminal of the input connector is coupled, through a pull-up resistor, to a voltage source. The least significant output terminal is adapted to have a ground potential applied thereto. By coupling the output connector of a circuit board to the input terminal of the next successive circuit board, the address, as determined by the voltage levels of the input connector automatically provide a thermometer address code for the coupled circuit boards. In addition, with a modest amount of additional apparatus, the thermometer address code size can be extended to provide 2N decoded addresses instead of N=1. The master circuit board can be automatically identified upon coupling of the circuit boards. The use of the present invention is particularly well adapted for stacked circuit boards.

Other features and advantages of the present invention will be more clearly understood upon reading of the following description and the accompanying drawings and claims.

### BRIEF DESCRIPTION OF THE DRAWINGS

FIG. 1 is an illustration of a thermometer code.

FIG. 2A a is a block diagram of a first embodiment of components on a circuit board that enable a group of series-coupled circuit boards to generate automatically the thermometer address code shown in FIG. 1 according to the present invention, while FIG. 2B illustrates how the address code is generated by the coupled circuit boards of FIG. 2A according to the present invention.

FIG. 3 is a block diagram of a second embodiment of components on a circuit board that enable a group of series-coupled circuit boards to generate automatically the thermometer address code shown in FIG. 1, as well as additional address codes, according to the present invention.

FIG. 4 illustrates the additional thermometer codes available from the second embodiment shown in FIG. 3 according to the present invention.

FIG. 5 illustrates a block diagram of a third embodiment of components on a circuit board that enables a group of series-coupled circuit boards to generate automatically an extended thermometer address code according to the present invention.

FIG. 6 illustrates the thermometer address code generated by a group of series-coupled circuit boards of the type shown in FIG. 5.

FIG. 7A is a block diagram of a board select circuit for use with any of circuit board embodiments illustrated above, while FIG. 7B illustrates the mapping for encoder of FIG. 7A according to the present invention.

FIG. 8 is a block diagram of a circuit included on a circuit board to determine when the circuit board is the master circuit board according to the present invention.

### DESCRIPTION OF THE PREFERRED EMBODIMENT

1. Detailed Description of the Drawings

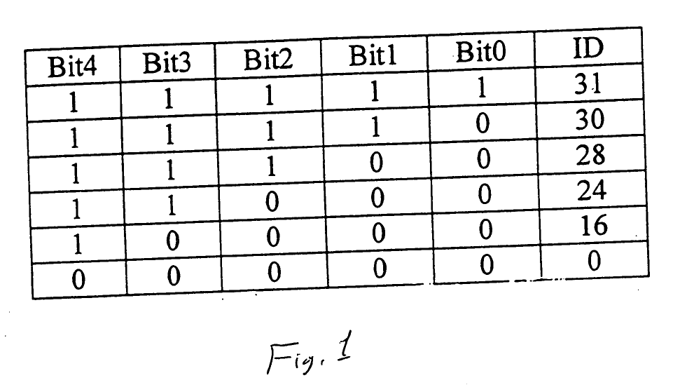

FIG. 1 has been described with respect to the related art.

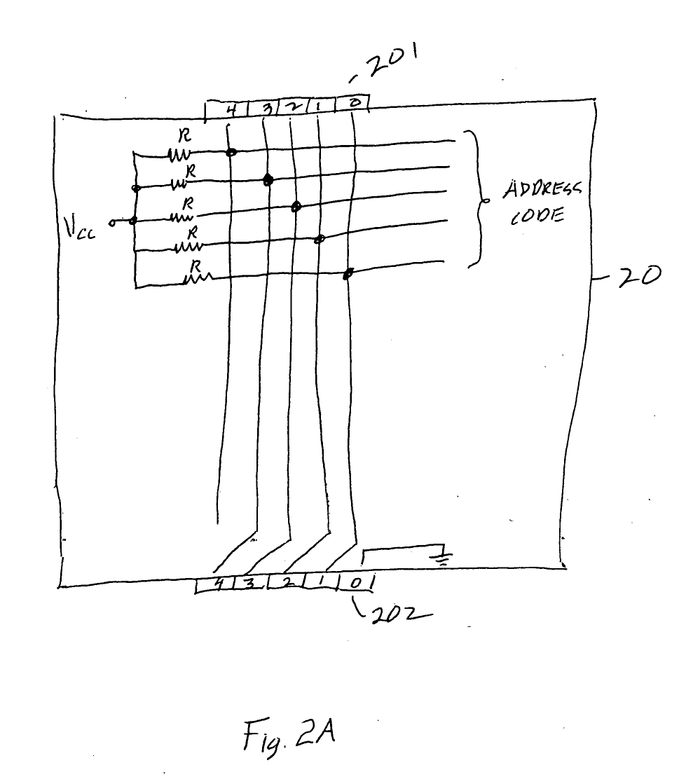

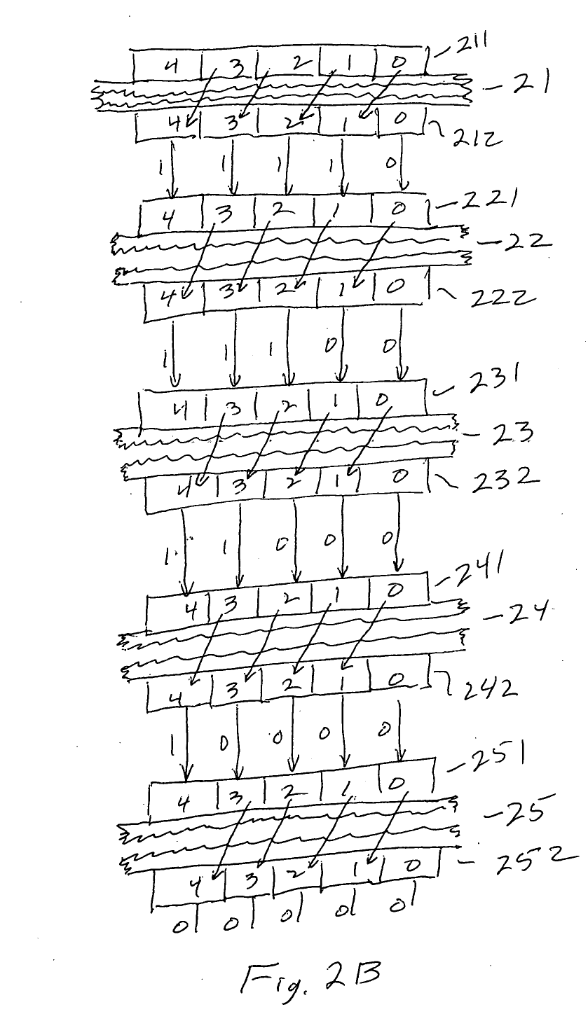

Referring to FIG. 2A, the features of circuit board 20 necessary for implementing a thermometer code for each of a series of circuit boards according to a first embodiment of the present invention is shown. The circuit board 20 includes and input connector 202 and an output connector 201. The connectors 201 and 202 are illustrated as having 5 terminals, 0 through 4, in order to illustrate the 5-position thermometer code of FIG. 1. Voltage source Vcc is coupled through pull-up resistors R to each input terminal 0 through 4 of connector 201. Conductors are coupled to the input terminals of connector 201 and logic signals applied to these conductors provide the logic signal address of the circuit board 20. The 0 terminal of the output connector 202 is coupled to ground potential. The terminal N of the input connector 201 is coupled to terminal N+1 of the output connector 202.

Referring next to FIG. 2B, the use of the circuit board of FIG. 2A for generating a thermometer code for each of a series of circuit boards 21 through 25 is illustrated. Circuit boards 21-through 25 each have an input connector 211 through 251 and an output connector 212 through 252. The output connector of each circuit board can be coupled to the input connector of the neighboring circuit board. As indicated in the discussion of circuit board 20 of FIG. 2A, the connectors 211 through 251 and 212 through 252 are shown with 5 terminals each. The terminals of each are labeled 0 through 4. Each circuit board has a voltage supply Vcc coupled through pull-up resistors R to each terminal of the input connectors 211 though 251. The 0 position of each output connector terminal 212 and 252 is coupled to ground potential. In addition, the terminals of the input connectors 211 through 251 are coupled to the terminals of the output connectors 212 through 252 in the following manner. The N^{th} position of the input connector is coupled to the n+1 position of the output connector. Thus, 0^{th} position of the input connector is coupled to the 1^{st} position of the output terminal. The 1^{st} position of the input connector is coupled to the 2^{nd} position of the output connector, etc. The coupling of the input connector terminals and the output connector terminals is illustrated by arrows in FIG. 2B. The address of the circuit board is determined by signals applied to the terminals of the input connectors. In this manner, the first circuit board 21 has a logic “1” in the five bit positions of the connector. This bit pattern provides a circuit board ID of 31 as indicated in the first line of FIG. 1. Because of the coupling of the input connector terminals and the output connector terminals, the input terminal of circuit board 22 has 4 logic “1”s and one logic “0” applied thereto. Note that the grounding of the output terminal bit position 0, consequently grounding the oth bit position of input connector 221 and the pull-up resistor coupled between the Vcc and the bit position 0 of connector insures that the first terminal of input connector 22 is a logic “0”. With each successive circuit board, a logic “1” is replaced by a logic “0” in the address. The Table shown in FIG. 1 therefore is reproduced by the configuration shown in FIG. 2B.

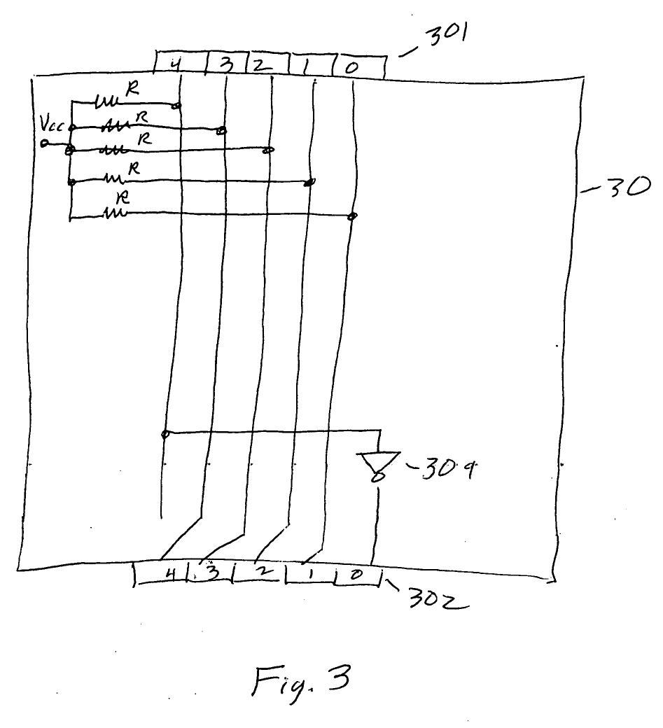

Referring to FIG. 3, a second circuit board 30 for implementing a thermometer address code scheme in a series of circuit boards is illustrated. The circuit board 30 includes a 5-terminal input connector 301 and a 5-terminal output connector 302. As in circuit board 20 of FIG. 2A, voltage source Vcc is coupled to each of the input terminals of connector 301 through pull-up resistor R. And the address of the circuit board is determined by the logic signals applied to the terminals of the input connector 301. Circuit board 30 differs from circuit board 20 in that, instead of having the terminal 0 of the output connector grounded, terminal 4 of the input connector 301 is coupled through inverting amplifier 309 to the terminal 0 of the output connector 302. As will be clear, with the circuit board implementation shown in FIG. 3 and inserted in FIG. 2B, the address codes for the circuit boards will those shown in FIG. 1.

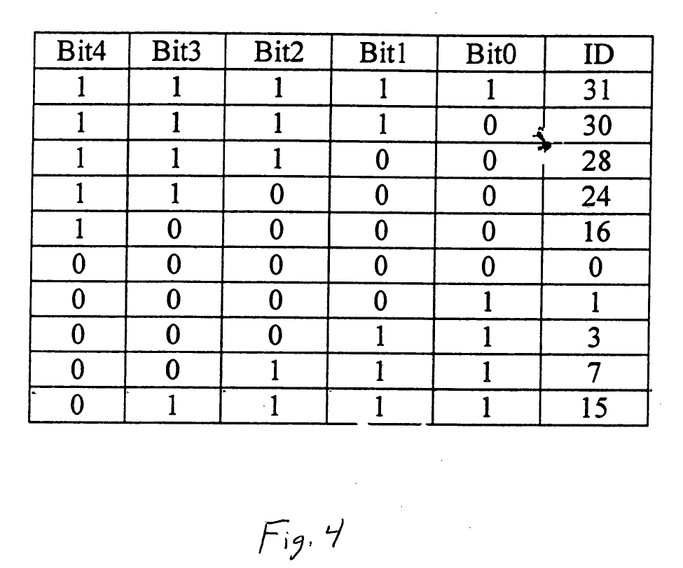

However, the implementation of the circuit board shown in FIG. 3 can provide an extended thermometer address code. This extension is a result of the inverting amplifier changing the logic bit “0” in the last line of FIG. 1 to a logic bit “1”. Similarly, when the address bits all are logic bit “0”s, the logic bit “1”s will be entered in the address bits. The result of this implementation of the thermometer code is shown in FIG. 4.

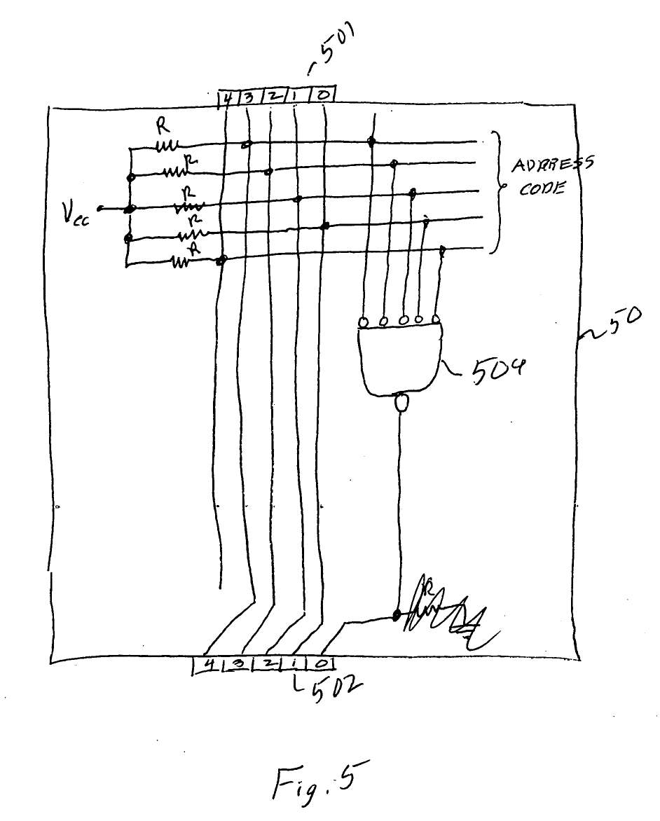

Referring to FIG. 5, another implementation of a circuit board providing an extended thermometer code is illustrated. In this third embodiment, the terminal n of the input connector 501 is coupled to the n+1 terminal of the output connector 502. Each input terminal is coupled to the voltage Vcc through a pull-up resistor R. The logic signals applied to the input terminals provide the address code. In addition, each circuit board includes a logic NAND gate 509. The first terminal of the input connector 501 is coupled to an inverting input terminal of the logic NAND gate 509. The remaining terminal of input connector 501 is coupled to input terminals of logic NAND gate 509. The output terminal of the logic NAND gate 509 is coupled to the first terminal of the output connector 502. Therefore, the logic NAND gate 509 will generate an output signal on the first circuit board in the series and a logic “0” will be applied to the first terminal of the output connector. On the second circuit board of the series, the first terminal of the input connector will be a logic “0”. Therefore, because all the other terminals of the input connector of the second board in the series are logic “1”s, a logic “1” will be applied to the first terminal of the output connector 502. This logic “1” will be propagated through the remaining addresses.

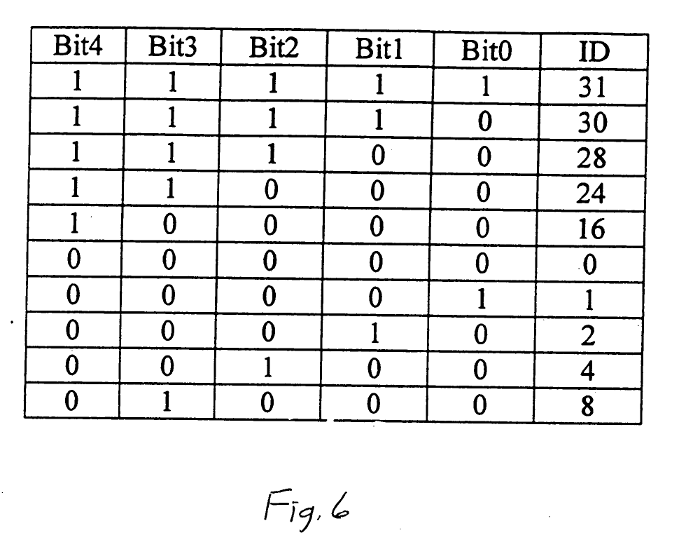

The code generated as a result of the series coupling of the circuit board 50 shown in FIG. 5 is illustrated in FIG. 6. An extended thermometer address code is provided although the code differs from the extended address code shown in FIG. 4.

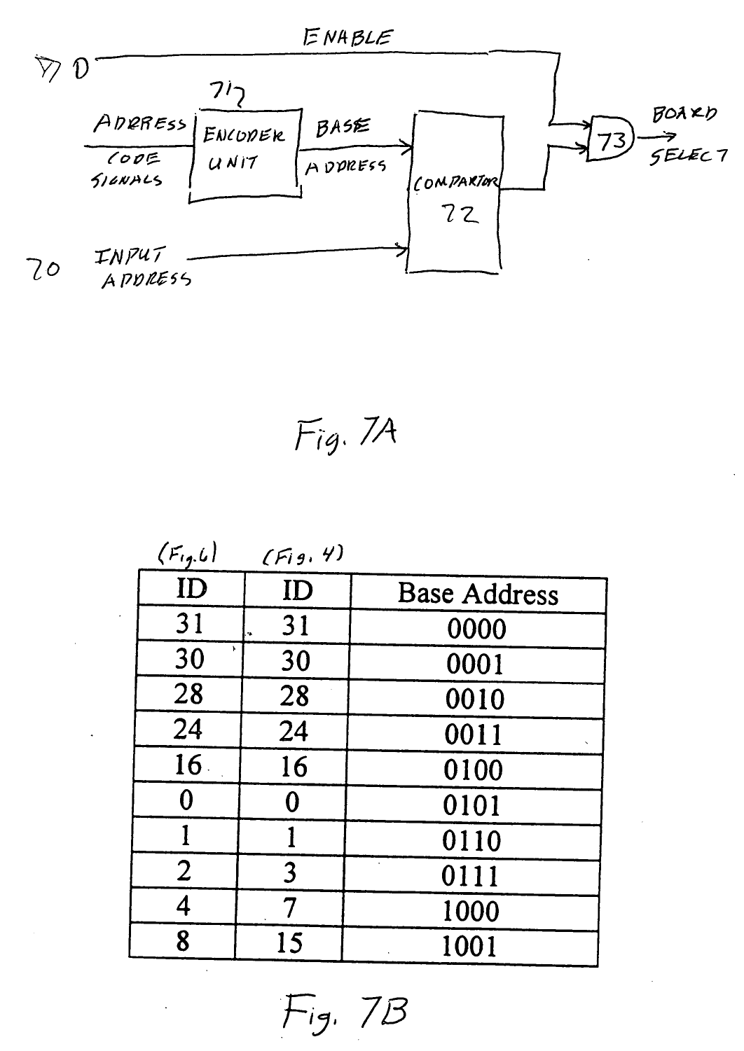

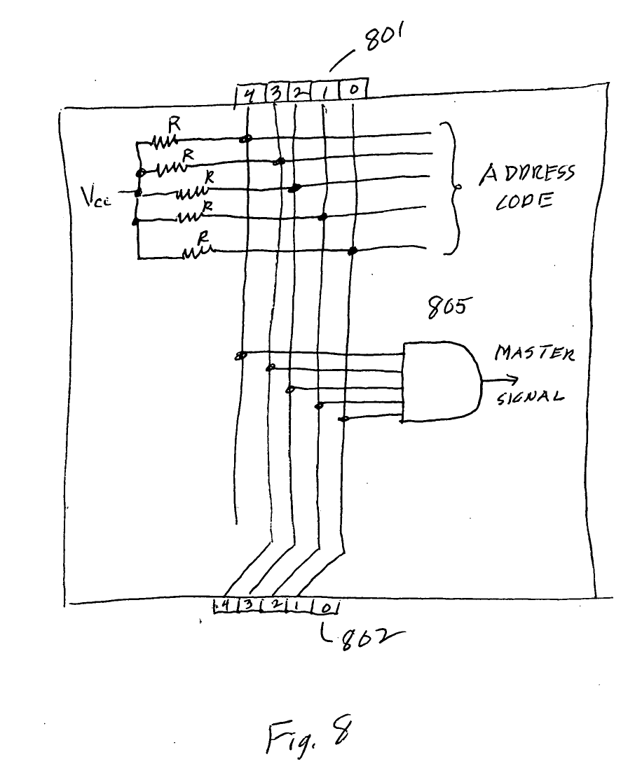

Referring to FIG. 7A, a board select circuit for inclusion on the series-coupled circuit boards is shown. From a source external to the circuit board 70, an ENABLE signal and an input address are applied to the circuit board 70. On the circuit board, the thermometer address signals, i.e., the signals applied to the input connector are applied to encoder 71. Encoder 71 converts the thermometer address signal code to a circuit board BASE ADDRESS signal. The circuit board BASE ADDRESS is applied to one set of terminals in comparator 72. The INPUT ADDRESS signals are applied to a second set of terminals of comparator 72. When the BASE ADDRESS signals and the INPUT ADDRESS signals are the same, the comparator applies a signal to a first terminal of logic AND gate 73. The ENABLE signal is applied to a second input terminal of logic AND gate 73. When a signal from comparator 72 and an ENABLE signal are applied to the logic AND gate 73, the logic AND gate 73 creates a BOARD SELECT signal. The presence of the BOARD SELECT signal enables the selected board to interact with other processing units.

Referring to FIG. 7B, one implementation of the encoder unit 71 is shown. The encoder unit 71 responds to the address signals, either as shown in FIG. 4 or in FIG. 6, and provides a base address. The base address is applied to the comparator 72 wherein a determination is made whether the circuit board base address is equal to the input address, the input address identifying the location of resources needed by a processing unit.

Although the circuit boards are identical in structure, the function of the individual circuit boards will vary. In particular, in many applications, the serially-connected boards would operate under the control of a master board. Because the configuration is expandable, the first circuit board of the serially-connected boards is selected to be the master board. This board will act as a master board only when an appropriate signal is present. The appropriate signal is generated according to present invention, by applying the logic signals from all of the terminals of the input connector 801 to the input terminal of logic AND gate 805, as shown in FIG. 8.

2. Operation of the Preferred Embodiment

The base address for each circuit board is determined by a thermometer address code and an encoder unit, the encoder unit converting the thermometer code addresses to a base address. This thermometer address is established at the terminals of the input connector. The thermometer address code is generated by the circuit boards automatically as a result of the displaced coupling of the input connector to the output connector. Using additional apparatus, the thermometer address code is expanded thereby reducing the number of terminals needed for the input and output connector. The present invention has the added advantage that all of the circuit boards in the series-coupled circuit boards can be identical.

All of the circuit boards have weak pull-up resistors tied to the terminals of the input connector. The voltage source and the pull-up resistors establish the logical high levels. When all the circuit boards are coupled, the impedance of the net is the parallel summation of all the resistors tied to the net. Therefore, the pull-up resistor value must be selected for the worst-case number of boards in order that the capacity of the logic circuits is sufficient to drive the resulting load. The master circuit board must be the first circuit board and this circuit board can be automatically selected.

In the preferred embodiment, the circuit boards are stacked together. In fact, the circuit board connectors can be used to provide both electrical and mechanical coupling between successive boards. Each circuit board is assigned a successively higher base address. By implementing a bus time-out mechanism, a software program can address the circuit boards in sequential order. The first bus time-out will therefore determine the number of boards in the series.

While the invention has been described with respect to the embodiments set forth above, the invention is not necessarily limited to these embodiments. Accordingly, other embodiments variations, and improvements not described herein are not necessarily excluded from the scope of the invention, the scope of the invention being defined by the following claims.

What is claimed is:

1. In a configuration having a plurality of series-coupled circuit boards, an apparatus on each circuit board for providing a thermometer address code, the apparatus comprising:
an output connector having N terminals, wherein the n^{th} terminal of the input connector is coupled to the (N+1)^{th} terminal of the output connector, wherein the oth terminal of the output connector is coupled to ground potential; and
a voltage source, each terminal of the input connector being coupled the voltage source through a pull-up resistor.

2. The apparatus as recited in claim 1 further comprising an inverting amplifier, wherein the n^{th} terminal of the input connector is coupled to an input terminal of the inverting amplifier, the output terminal of the inverting amplifier being coupled to the oth terminal of the output connector.

3. The apparatus as recited in claim 1 further including a logic NAND gate, each terminal of the input connector coupled to an inverting terminal of the logic NAND gate, the output terminal of the logic NAND gate being coupled to the oth terminal of the output connector.

4. The apparatus as recited in claim 1 further comprising a logic AND gate, each terminal of the input connector being coupled to an input terminal of the logic AND gate, the output terminal of the logic AND gate providing signal when the circuit board is a the master circuit board of the group of series-coupled circuit boards.

5. The apparatus of claim 1 wherein the logic signals applied to the terminals of the input connector are the address code of the circuit board.

6. The apparatus as recited in claim 5 further comprising:
an encoder unit, the address code of the circuit board being applied to the input terminals of the encoder unit, a circuit board base address being applied to the output terminals of the encoder unit; and
a comparator, the comparator having the circuit board base address applied to one set of input terminal, the comparator having an input address applied to a second set of input terminals, the comparator generating a board select signal when the circuit board base address and the input address are the same.

7. A method for providing a thermometer address code for group of series-coupled circuit boards, the method comprising:
on each circuit board, coupling the n^{th} terminal of an N terminal input connector to the (N+1)^{th} terminal of N terminal output connector;
applying a voltage through a pull-up resistor to each terminal of the input connector; and
coupling a ground potential to the oth terminal of the output connector, wherein the voltage levels of the terminals of the input connector are the address code.

8. The method as recited in claim 7 further comprising:
instead of the ground potential, coupling an output terminal of an inverting amplifier to the 0^{th} terminal of the output connector; and
coupling an input terminal of the inverting amplifier to the n^{th} terminal of the input connector.

9. The method as recited in claim 7 further comprising:
coupling an output terminal of logic NAND gate to the oth terminal of the output connector; and
coupling each terminal of the input connector to an inverting input terminal of the logic NAND gate.

10. The method as recited in claim 7 further comprising coupling each terminal of the input connector to an input terminal of a logic AND gate, the logic AND gate generating a signal when the circuit board is the master circuit board.

11. The method as recited in claim 7 further comprising:
converting the circuit board address code to a base address;
comparing the base address with an input address; and
when the base address and the input address are the same, generating a board select signal.

12. An apparatus for providing a thermometer address code for each of a group of serially-coupled circuit boards, wherein each circuit board comprises:
an input connector having N terminals;
an output connector having N terminals, wherein the n h input terminal of the input connector is coupled to the (N+1)^{th} terminal of the output connector;
a voltage source;
N resistors, each terminal of the input connector being coupled through a resistor to the voltage source;
wherein the 0^{th} terminal of the output connector is coupled to ground potential, the voltage levels of the terminal of the input connector providing the address code.

13. The circuit board as recited in claim 12 further including an inverting amplifier, the input terminal of the inverting amplifier coupled to the n^{th} terminal of the input connector, the output terminal of the inverting amplifier replacing the ground potential at the oth terminal of the output connector.

14. The circuit board as recited in claim 12 further including:
a logic NAND gate, the output terminal of logic NAND gate coupled to the 0^{th} terminal of the output connector, each terminal of the input connector coupled to one of the inverting input terminals of the logic NAND gate.

15. The circuit board as recited in claim 12 further including a logic AND gate, each input terminal of the logic AND gate being coupled to a terminal of the input connector, the output terminal of the logic AND gate generating a signal when the circuit board is the master circuit board.

16. The circuit board as recited in claim 12 further including:
an encoder unit, the encoder unit coupled to the terminals of the input connector, the encoder converting the address code to a base address; and
a comparison coupled to the encoder unit, the comparison unit having an input address applied thereto, the comparison unit generating a board select signal when the base address and the input address are equal.
